(19) United States
(12) Patent Application Publication
(10) Pub. No.: US 2024/0038160 A1
(43) Pub. Date: Feb. 1, 2024

(54) PIXEL CIRCUIT AND DISPLAY DEVICE

(71) Applicant: WUHAN CHINA STAR OPTOELECTRONICS SEMICONDUCTOR DISPLAY TECHNOLOGY CO., LTD, Wuhan, Hubei (CN)

(72) Inventors: Mian Zeng, Wuhan, Hubei (CN); Liang Sun, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/622,778

(22) PCT Filed: Dec. 9, 2021
(86) PCT No.: PCT/CN2021/136813

§ 371 Date: Dec. 24, 2021

(30) Foreign Application Priority Data
Dec. 3, 2021 (CN) 202111464063.9

(51) Int. Cl. G09G 3/3233; G09G 3/3258; H10K 59/121

(52) U.S. Cl. CPC G09G 3/3233; G09G 3/3258; H10K 59/1216; H10K 59/1213

(57) ABSTRACT

Disclosed is a pixel circuit and a display device. The pixel circuit includes a driving unit, a light-emitting control unit, and a compensation unit. The driving unit and light-emitting control unit are electrically connected between a first power input terminal and a light-emitting unit. The compensation unit is electrically connected between the driving unit and the light-emitting control unit. A first capacitor is electrically connected between the compensation unit and the control signal input terminal.

### CROSS REFERENCE TO RELATED APPLICATION

This application claims priority to Chinese Application No. 202111464063.9 filed on Dec. 3, 2021. The entire disclosure of the above applications is incorporated herein by reference.

### FIELD OF THE DISCLOSURE

The application relates to a field of display technology, and in particular to a pixel circuit and a display device.

### BACKGROUND

With the development of multimedia, display devices have become more important. Correspondingly, the requirements for various types of display devices are getting higher and higher. Especially in the field of smart phones, ultra-high frequency driving displays, low power consumption driving displays, and low frequency driving displays are all important development directions at this stage and in the future.

Pixel circuits are crucial elements for driving light-emitting units of a display device to emit light, and the stability and sensitivity of their working performance directly affect the display effect of the display device. At present, transistors used in 7T1C (consisting of 7 transistors and 1 storage capacitor) pixel circuits are mostly low-temperature polysilicon transistors. This is because of the low cost, simple process and mature technology of this type of transistors, but an obvious defect thereof is a relatively large leakage current which is mainly manifested in that an obvious leakage current problem is caused in the transistors directly connected to the driving transistor in the pixel circuit have, which causes the driving transistors to operate abnormally and then causes the display abnormality. The current solution is to implement the transistors connected to the driving transistor by double-gate transistors or replace them with metal oxide transistors. However, due to the large parasitic capacitance of the double-gate transistors, the leakage current cannot be effectively relieved, while the metal oxide transistors have the problem in high cost and complicated manufacture process.

The current pixel circuit has a technical problem in large leakage currents.

### SUMMARY

The present disclosure provides a pixel circuit and a display device, which are used to alleviate a technical problem in large leakage currents in the current pixel circuits.

The present disclosure provides a pixel circuit. The pixel circuit includes a driving unit, a light-emitting control unit, and a compensation unit. The driving unit is electrically connected between a first power input terminal and a light-emitting unit. The light-emitting control unit is electrically connected between the first power input terminal and the light-emitting unit and electrically connected to the driving unit. The light-emitting control unit is electrically connected to a control signal input terminal. The compensation unit is electrically connected between the driving unit and the light-emitting control unit. A first capacitor is electrically connected between the compensation unit and the control signal input terminal.

Optionally, the compensation unit comprises a double-gate transistor, the double-gate transistor comprises a first channel and a second channel. A first terminal of the first capacitor is electrically connected between the first channel and the second channel.

Optionally, the double-gate transistor comprises a first sub-transistor and a second sub-transistor. The first sub-transistor includes the first channel, a first drain electrically connected to the first terminal of the first capacitor, and a first source, electrically connected between the driving unit and the light-emitting control unit. The second sub-transistor includes the second channel, a second source electrically connected to the first drain and a second drain electrically connected to the driving unit.

Optionally, the first terminal of the first capacitor is electrically connected to the second source.

Optionally, the light-emitting control unit comprises a first light-emitting control unit and a second light-emitting control unit. The control signal input terminal comprises a first control signal input terminal electrically connected to the first light-emitting control unit and a second control signal input terminal electrically connected to the second light-emitting control unit.

Optionally, the first light-emitting control unit is electrically connected between the first power input terminal and the driving unit, the second light-emitting control unit is electrically connected between the driving unit and the light-emitting unit.

Optionally, a second terminal of the first capacitor is electrically connected to the first control signal input terminal.

Optionally, a second terminal of the first capacitor is electrically connected to the second control signal input terminal.

Optionally, the pixel circuit further includes a reset unit, an input unit, and a storage unit. The reset unit is electrically connected between a reset signal input terminal and the light-emitting unit. The input unit is electrically connected between a data signal input terminal and the driving unit. The storage unit is electrically connected between the first power input terminal and the driving unit.

Optionally, the driving unit comprises a first transistor, a gate of the first transistor is electrically connected to a drain of the double-gate transistor.

Optionally, the first light-emitting control unit comprises a second transistor, the second light-emitting control unit comprises a third transistor, the gate, a source, and a drain of the first transistor are electrically connected to the drain of the double-gate transistor, a drain of the second transistor, and a source of the third transistor respectively. A gate, a source, and the drain of the second transistor are electrically connected to the first control signal input terminal, the first power input terminal, and the source of the first transistor respectively, a gate, the source, and a drain of the third transistor are electrically connected to the second control signal input terminal, the drain of the transistor, and the light-emitting unit respectively.

Optionally, the input unit comprises a fourth transistor, a gate, a source, and a drain of the fourth transistor are electrically connected to a first scan signal input terminal, the data signal input terminal, and the source of the first transistor, respectively.

Optionally, the reset unit comprises a fifth transistor, a gate, a source, and a drain of the fifth transistor are electrically connected to a second scan signal input terminal, the reset signal input terminal, and the drain of the third transistor, respectively.

Optionally, the storage unit comprises a second capacitor, opposite two terminals of the second capacitor are electrically connected to the first power input terminal and the gate of the first transistor respectively.

Optionally, a gate of the double-gate transistor is electrically connected to the second scan signal input terminal.

Optionally, the double-gate transistor is a low-temperature polysilicon transistor.

Optionally, the first, second, third, fourth, fifth transistors are low-temperature polysilicon transistors.

According to another embodiment of the present disclosure, a display device comprising a pixel circuit is provided. The pixel circuit includes a driving unit, a light-emitting control unit, and a compensation unit. The driving unit is electrically connected between a first power input terminal and a light-emitting unit. The light-emitting control unit is electrically connected between the first power input terminal and the light-emitting unit and electrically connected to the driving unit. The light-emitting control unit is electrically connected to a control signal input terminal. The compensation unit is electrically connected between the driving unit and the light-emitting control unit. A first capacitor is electrically connected between the compensation unit and the control signal input terminal.

Optionally, the compensation unit comprises a double-gate transistor, the double-gate transistor comprises a first channel and a second channel, a first terminal of the first capacitor is electrically connected between the first channel and the second channel, and a second terminal of the first capacitor is electrically connected to the light-emitting control unit.

According to still another embodiment of the present disclosure, A pixel circuit is provided. The pixel circuit includes a driving unit, a light-emitting control unit, a first capacitor, and a compensation unit. The driving unit is electrically connected between a first power input terminal and a light-emitting unit. The light-emitting control unit is electrically connected between the first power input terminal and the light-emitting unit and electrically connected to the driving unit. The light-emitting control unit is electrically connected to a control signal input terminal. The compensation unit is electrically connected between the driving unit and the light-emitting control unit. The first capacitor is electrically connected between the compensation unit and the control signal input terminal. A first terminal of the first capacitor is electrically connected between the first channel and the second channel, and a second terminal of the first capacitor is electrically connected to the light-emitting control unit.

The present disclosure provides a pixel circuit and a display device. The pixel circuit comprises a driving unit, a light-emitting control unit, and a compensation unit. Both of the driving unit and the light-emitting control unit are electrically connected between a first power input terminal and a light-emitting unit. The light-emitting control unit is electrically connected to a control signal input terminal. The compensation unit is electrically connected between the driving unit and the light-emitting control unit, and a first capacitor is electrically connected between the compensation unit and the control signal input terminal. In the application, the first capacitor is electrically connected between the compensation unit and the control signal input terminal. The coupling effect of the first capacitor is used to reduce or eliminate the parasitic capacitance in the compensation unit, thereby decreasing the parasitic voltage in the compensation unit. This effectively alleviates the leakage problem of the compensation unit to the driving unit, enhances the stability of the pixel circuit, and improves the display quality of the display device.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a schematic structural diagram of a first pixel circuit provided by an embodiment of the present disclosure.

FIG. 2 is a partial timing chart of the pixel circuit shown in FIG. 1.

FIG. 3 is a schematic structural diagram of a second pixel circuit provided by an embodiment of the present disclosure.

FIG. 4 is a partial timing diagram of the pixel circuit shown in FIG. 3.

### DETAILED DESCRIPTION

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The present disclosure provides a pixel circuit and a display device. The pixel circuit comprises a driving unit, a light-emitting control unit, and a compensation unit. Both of the driving unit and the light-emitting control unit are electrically connected between a first power input terminal and a light-emitting unit. The light-emitting control unit is electrically connected to a control signal input terminal. The compensation unit is electrically connected between the driving unit and the light-emitting control unit, and a first capacitor is electrically connected between the compensation unit and the control signal input terminal. In the application, the first capacitor is electrically connected between the compensation unit and the control signal input terminal. The coupling effect of the first capacitor is used to reduce or eliminate the parasitic capacitance in the compensation unit, thereby decreasing the parasitic voltage in the compensation unit. This effectively alleviates the leakage problem of the compensation unit to the driving unit, enhances the stability of the pixel circuit, and improves the display quality of the display device.

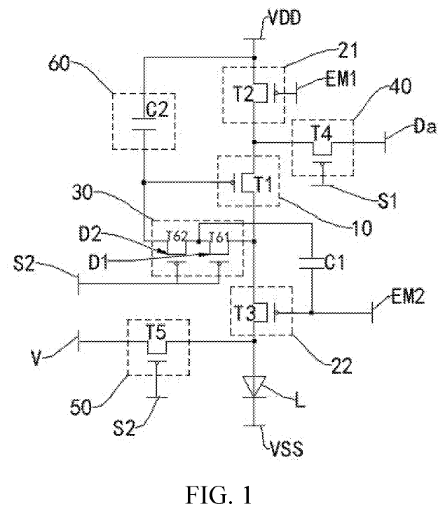

Please refer to FIG. 1. FIG. 1 is a schematic structural diagram of a first pixel circuit provided by an embodiment of the present disclosure. The pixel circuit comprises a driving unit 10, a light-emitting control unit, a compensation unit 30, an input unit 40, a reset unit 50, and a storage unit 60. The light-emitting control unit may comprise a first light-emitting control unit 21 and a second light-emitting control unit 22. The driving unit 10 and the light-emitting control unit are used to drive and control a light-emitting unit L to emit light; the compensation unit 30 is used to compensate a control terminal voltage of the drive unit 10. The input unit 40 is used to input a data signal and drive the light-emitting unit L through the driving unit 10 to emit light; the reset unit 50 is used to reset the control terminal voltage of the driving unit and also reset the input terminal voltage of the light-emitting unit L. The storage unit 60 is used to store the control terminal voltage of the driving unit 10.

The driving unit 10 is electrically connected between a first power input terminal VDD and the light-emitting unit L. The first power input terminal VDD is used to input a first power signal to the pixel circuit. The driving unit 10 drives the first power signal inputted from the first power input terminal VDD to be transmitted to the light-emitting unit L, and then the light-emitting unit L is driven to emit light.

The light-emitting control unit is electrically connected between the first power input terminal VDD and the light-emitting unit L, and is electrically connected to the driving unit 10. The light-emitting control unit is also electrically connected to a control signal input terminal and controls the electrical conduction relationship between the first power input terminal VDD and the light-emitting unit L under an effect of a control signal inputted from the control signal input terminal. The light-emitting control unit and the driving unit 10 jointly control whether the first power signal flows to the light-emitting unit L and then control the light-emitting state of the light-emitting unit L. For example, when the light-emitting control unit and the driving unit 10 are both turned on, the driving unit 10 transmits the first power signal to the light-emitting unit L to achieve the light-emitting of the light-emitting unit L; when the light-emitting control unit is turned off, the path between the first power input terminal VDD and the light-emitting unit L is cut off, and the light-emitting unit L does not emit light. The light-emitting control unit achieve the switch between the on state and the off state under the effect of the signal output from the control signal input terminal.

The light-emitting control unit comprises a first light-emitting control unit 21 and a second light-emitting control unit 22. The first light-emitting control unit 21 is electrically connected between the first power input terminal VDD and the driving unit 10. The second light-emitting control unit 22 is electrically connected between the driving unit 10 and the light-emitting unit L. Therefore, the path between the first power input terminal VDD and the driving unit 10 is controlled by the first light-emitting control unit 21, and the path between the driving unit 10 and the light-emitting unit L is controlled by the second light-emitting control unit 22, thereby achieving that the first light-emitting control unit 21 and the second light-emitting control unit 22 jointly control the electrical conduction relationship between the first power input unit VDD and the light-emitting unit L. The first light-emitting control unit 21 is electrically connected to a first control signal input terminal EM1, and is turned on and off under an effect of a first control signal inputted from the first control signal input terminal EM1. The second light-emitting control unit 22 is electrically connected to s second control signal input terminal EM2, and is turned on and off under an effect of a second control signal inputted from the second control signal input terminal EM2.

The compensation unit 30 is electrically connected between the driving unit 10 and the light-emitting control unit. Specifically, the compensation unit 30 is directly electrically connected to the second light-emitting control unit 22, and the compensation unit 30 is also electrically connected to a second scan signal input terminal S2. The second scan signal input terminal S2 provides a second scan signal to the compensation unit and drives the compensation unit 30 to compensate the control terminal voltage of the driving unit 10.

A first capacitor C1 is electrically connected between the compensation unit 30 and the control signal input terminal. Specifically, the first capacitor C1 is electrically connected between the compensation unit 30 and the second control signal input terminal EM2, and couples the parasitic capacitance generated in the compensation unit 30 to reduce or eliminate the parasitic capacitance. In the embodiment, the coupling effect of the first capacitor C1 is used to reduce or eliminate the parasitic capacitance in the compensation unit 30, thereby decreasing the parasitic voltage in the compensation unit 30. This effectively alleviates the leakage problem of the compensation unit 30 to the driving unit 10, and is beneficial to enhance the stability of the pixel circuit and improve the display quality of the display device.

The input unit 40 is electrically connected between a data signal input terminal Da and the driving unit 10 for transmitting a data signal to the driving unit 10 to regulate the driving state of the driving unit 10. The input unit 40 is also electrically connected to a first scan signal input terminal S1, and a first scan signal provided by the first scan signal input terminal S1 controls the input unit 40 to be turned on or turned off. Specifically, one terminal of the input unit 40 is connected between the first light-emitting control unit 21 and the driving unit 10.

The reset unit 50 is electrically connected between a reset signal input terminal V and the light-emitting unit L for providing a reset signal to the light-emitting unit L. The reset unit 50 is also electrically connected to the second scan signal input terminal S2. The second scan signal provided by the second scan signal input terminal S2 controls the reset unit 50 to be turned on or turned off. Specifically, one terminal of the reset unit 50 is connected between the light-emitting unit L and the second light-emission control unit 22, and the reset unit 50 is electrically connected to the control terminal of the driving unit 10 through the second light-emission control unit 22 and the compensation unit 30 for achieving the reset of the voltage of the control terminal of the driving unit 10.

The storage unit 60 is electrically connected between the first power input terminal VDD and the driving unit 10 for storing the voltage of the control terminal of the driving unit 10. The other terminal of the light-emitting unit L is electrically connected to a second power input terminal VSS. The second power input terminal VSS provides a second power signal to the light-emitting unit L. Generally, the first power signal and the second power signal are both voltage signals, and the voltage of the first power signal is greater than the voltage of the second power signal.

The compensation unit 30 comprises a double-gate transistor. The double-gate transistor comprises a first channel D1 and a second channel D2. The first terminal of the first capacitor C1 is electrically connected between the first channel D1 and the second channel D2. The second terminal of the first capacitor C1 is electrically connected to the second control signal input terminal EM2. The parasitic capacitance in the double-gate transistor is eliminated or reduced through the coupling effect of the first capacitor C1. The gate of the double-gate transistor is electrically connected to the second scan signal input terminal S2.

The double-gate transistor comprises a first sub-transistor T61 and a second sub-transistor T62. The first sub-transistor T61 comprises the first channel D1, and further comprises a first source and a first drain disposed at opposite two ends of the first channel D1. The second sub-transistor T62 comprises the second channel D2, and further comprises a second source and a second drain disposed at opposite two ends of the second channel D2. The first drain is electrically connected to the second source. The first terminal of the first capacitor C1 is electrically connected to the first drain or electrically connected to the second source. The first source is electrically connected to the driving unit 10. The second drain is electrically connected to the control terminal of the driving unit 10. The gate of the first sub-transistor T61 and the gate of the second sub-transistor T62 are both electrically connected to the second scan signal input terminal S2.

The driving unit 10 comprises a first transistor T1. The first light-emitting control unit 21 comprises a second transistor T2. The second light-emitting control unit 22 comprises a third transistor T3. The gate, source, and drain of the first transistor T1 are electrically connected to the drain of the double-gate transistor, the drain of the second transistor T2, and the source of the third transistor T3, respectively. The gate and the source of the second transistor T2 are electrically connected to the first control signal input terminal EM1 and the first power input terminal VDD, respectively. The gate and the drain of the third transistor T3 are electrically connected to the second control signal input terminal EM2 and the light-emitting unit L, respectively.

The input unit 40 comprises a fourth transistor T4. The gate, source, and drain of the fourth transistor T4 are electrically connected to the first scan signal input terminal S1, the data signal input terminal Da, and the source of the first transistor T1, respectively. The reset unit 50 comprises a fifth transistor T5. The gate, source, and drain of the fifth transistor T5 are electrically connected to the second scan signal input terminal S2, the reset signal input terminal V, and the drain of the third transistor T3, respectively. The storage unit 60 comprises a second capacitor C2. The opposite two terminals of the second capacitor C2 are electrically connected to the first power input terminal VDD and the gate of the first transistor T1, respectively.

All of the first transistor T1, the second transistor T2, the third transistor T3, the fourth transistor T4, the fifth transistor T5, and the double-gate transistor are low temperature polysilicon transistors. It can be understood that each pixel circuit provided in the embodiment uses low-temperature polysilicon transistors. Since the cost of the low-temperature polysilicon transistors is low and manufacture process thereof is simple and mature, the embodiment can reduce product costs and improve product yield and quality.

The first transistor T1, the second transistor T2, the third transistor T3, the fourth transistor T4, the fifth transistor T5, and the double-gate transistor mentioned in the embodiment are all symmetrical transistors, that is, the source and the drain of each transistor can be interchanged without considering the relationship between the direction of the current and the source and drain of the transistor.

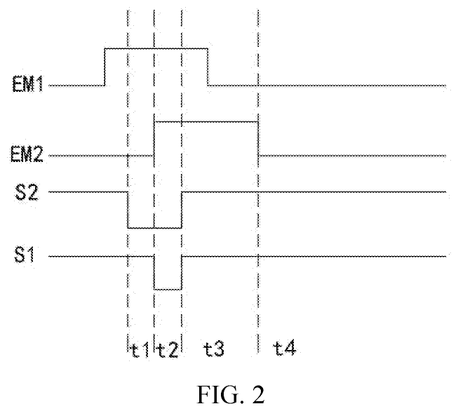

The operation principle of the pixel circuit provided in the embodiment will be described below by referring to FIG. 2. There are at least the following operation stages for the pixel circuit.

In the t1 time period, it relates to an initialization phase. In this phase, both of the second control signal input terminal EM2 and the second scan signal input terminal S2 input low-level signals. The fifth transistor T5, the third transistor T3, and the double-gate transistor are turned on. The reset signal input terminal V initializes the gate voltage of the first transistor T1.

In the t2 time period, it relates to a charge phase for the driving unit. In this phase, both of the first scan signal input terminal S1 and the second scan signal input terminal S2 input low-level signals, and both of the first control signal input terminal EM1 and the second control signal input terminal EM2 input high-level signals. The fourth transistor T4, the fifth transistor T5, and the double-gate transistor are turned on. The second transistor T2 and the third transistor T3 are turned off. The data signal input from the data signal input terminal Da charges the gate of the first transistor T1 and is stored in the second capacitor C2. At the same time, the reset signal input terminal V resets the input terminal of the light-emitting unit L.

In the t3 time period, it related to a coupling phase for the first capacitor C1. At the initial moment of this phase, the first scan signal input terminal S1 and the second scan signal input terminal S2 are switched to input high-level signals, the double-gate transistor is turned off, and the second control signal input terminal EM2 inputs a high-level signal. Under the coupling effect of the first capacitor C1, the internal potential of the double-gate transistor is coupled to a higher value. At the last moment of the t3 time period, the input signal of the second control signal input terminal EM2 changes to the low level from the high level. Under the coupling effect of the first capacitor C1, the internal potential of the double-gate transistor is coupled to a lower value and then less than the gate potential of the first transistor T1, thereby reducing or eliminating the leakage current from the double-gate transistor to the first transistor T1.

In the t4 time period, it related to a light-emitting phase. In this phase, both of the first control signal input terminal EM1 and the second control signal input terminal EM2 input low-level signals. The second transistor T2 and the third transistor T3 are turned on. Under the effect of the data signal stored in the second capacitor C2, the first transistor T1 drives the light-emitting unit L to emit light.

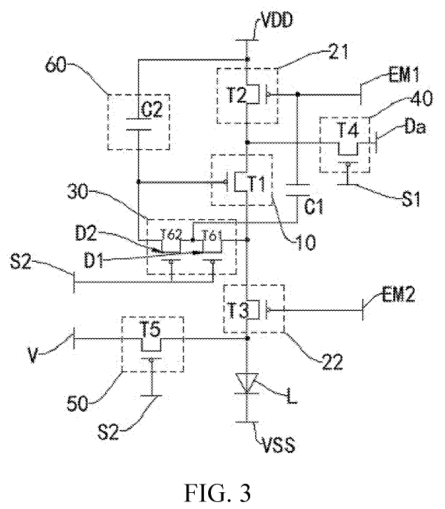

Please refer to FIG. 3. FIG. 3 is a schematic structural diagram of a second pixel circuit provided by an embodiment of the present disclosure. The pixel circuit shown in FIG. 3 has the same or similar features as the pixel circuit shown in FIG. 1. The features of the pixel circuit shown in FIG. 3 will be described below. Please refer to the description of the above-mentioned embodiment for the parts that are not described in detail.

The pixel circuit comprises a driving unit 10, a light-emitting control unit, a compensation unit 30, an input unit 40, a reset unit 50, and a storage unit 60. The light-emitting control unit may comprise a first light-emitting control unit 21 and a second light-emitting control unit 22.

The driving unit 10 is electrically connected between a first power input terminal VDD and the light-emitting unit L. The first power input terminal VDD is used to input a first power signal to the pixel circuit. The driving unit 10 drives the first power signal inputted from the first power input terminal VDD to be transmitted to the light-emitting unit L, and then the light-emitting unit L is driven to emit light.

The light-emitting control unit is electrically connected between the first power input terminal VDD and the light-emitting unit L, and is electrically connected to the driving unit 10. The light-emitting control unit is also electrically connected to a control signal input terminal and controls the electrical conduction relationship between the first power input terminal VDD and the light-emitting unit L under an effect of a control signal inputted from the control signal input terminal. The light-emitting control unit comprises a first light-emitting control unit 21 and a second light-emitting control unit 22. The first light-emitting control unit 21 is electrically connected between the first power input terminal VDD and the driving unit 10. The second light-emitting control unit 22 is electrically connected between the driving unit 10 and the light-emitting unit L. The first light-emitting control unit 21 is electrically connected to a first control signal input terminal EM1, and is turned on and off under an effect of a first control signal inputted from the first control signal input terminal EM1. The second light-emitting control unit 22 is electrically connected to s second control signal input terminal EM2, and is turned on and off under an effect of a second control signal inputted from the second control signal input terminal EM2.

The compensation unit 30 is electrically connected between the driving unit 10 and the light-emitting control unit. Specifically, the compensation unit 30 is directly electrically connected to the second light-emitting control unit 22, and the compensation unit 30 is also electrically connected to a second scan signal input terminal S2. The second scan signal input terminal S2 provides a second scan signal to the compensation unit 30 and drives the compensation unit 30 to compensate the control terminal voltage of the driving unit 10.

A first capacitor C1 is electrically connected between the compensation unit 30 and the control signal input terminal. Specifically, the first capacitor C1 is electrically connected between the compensation unit 30 and the first control signal input terminal EM1, and couples the parasitic capacitance generated in the compensation unit 30 to reduce or eliminate the effect of the parasitic capacitance, which effectively alleviates the leakage problem of the compensation unit 30 to the driving unit 10, and is beneficial to enhance the stability of the pixel circuit and improve the display quality of the display device.

The input unit 40 is electrically connected between a data signal input terminal Da and the driving unit 10 for transmitting a data signal to the driving unit 10 to regulate the driving state of the driving unit 10. The input unit 40 is also electrically connected to a first scan signal input terminal S1, and a first scan signal provided by the first scan signal input terminal S1 controls the input unit 40 to be turned on or turned off. Specifically, one terminal of the input unit 40 is connected between the first light-emitting control unit 21 and the driving unit 10.

The reset unit 50 is electrically connected between a reset signal input terminal V and the light-emitting unit L for providing a reset signal to the light-emitting unit L. The reset unit 50 is also electrically connected to the second scan signal input terminal S2. The second scan signal provided by the second scan signal input terminal S2 controls the reset unit 50 to be turned on or turned off. Specifically, one terminal of the reset unit 50 is connected between the light-emitting unit L and the second light-emission control unit 22, and the reset unit 50 is electrically connected to the control terminal of the driving unit 10 through the second light-emission control unit 22 and the compensation unit 30 for achieving the reset of the voltage of the control terminal of the driving unit 10.

The storage unit 60 is electrically connected between the first power input terminal VDD and the driving unit 10 for storing the voltage of the control terminal of the driving unit 10. The other terminal of the light-emitting unit L is electrically connected to a second power input terminal VSS. The second power input terminal VSS provides a second power signal to the light-emitting unit L. Generally, the first power signal and the second power signal are both voltage signals, and the voltage of the first power signal is greater than the voltage of the second power signal.

The compensation unit 30 comprises a double-gate transistor. The double-gate transistor comprises a first channel D1 and a second channel D2. The first terminal of the first capacitor C1 is electrically connected between the first channel D1 and the second channel D2. The second terminal of the first capacitor C1 is electrically connected to the first control signal input terminal EM1. The parasitic capacitance in the double-gate transistor is eliminated or reduced through the coupling effect of the first capacitor C1. The gate of the double-gate transistor is electrically connected to the second scan signal input terminal S2.

Further, the double-gate transistor comprises a first sub-transistor T61 and a second sub-transistor T62. The first sub-transistor T61 comprises the first channel D1, and further comprises a first source and a first drain disposed at opposite two ends of the first channel D1. The second sub-transistor T62 comprises the second channel D2, and further comprises a second source and a second drain disposed at opposite two ends of the second channel D2. The first drain is electrically connected to the second source. The first terminal of the first capacitor C1 is electrically connected to the first drain or electrically connected to the second source. The first source is electrically connected to the driving unit 10. The second drain is electrically connected to the control terminal of the driving unit 10. The gate of the first sub-transistor T61 and the gate of the second sub-transistor T62 are both electrically connected to the second scan signal input terminal S2.

The driving unit 10 comprises a first transistor T1. The first light-emitting control unit 21 comprises a second transistor T2. The second light-emitting control unit 22 comprises a third transistor T3. The gate, source, and drain of the first transistor T1 are electrically connected to the drain of the double-gate transistor, the drain of the second transistor T2, and the source of the third transistor T3, respectively. The gate and the source of the second transistor T2 are electrically connected to the first control signal input terminal EM1 and the first power input terminal VDD, respectively. The gate and the drain of the third transistor T3 are electrically connected to the second control signal input terminal EM2 and the light-emitting unit L, respectively.

The input unit 40 comprises a fourth transistor T4. The gate, source, and drain of the fourth transistor T4 are electrically connected to the first scan signal input terminal S1, the data signal input terminal Da, and the source of the first transistor T1, respectively. The reset unit 50 comprises a fifth transistor T5. The gate, source, and drain of the fifth transistor T5 are electrically connected to the second scan signal input terminal S2, the reset signal input terminal V, and the drain of the third transistor T3, respectively. The storage unit 60 comprises a second capacitor C2. The opposite two terminals of the second capacitor C2 are electrically connected to the first power input terminal VDD and the gate of the first transistor T1, respectively.

All of the first transistor T1, the second transistor T2, the third transistor T3, the fourth transistor T4, the fifth transistor T5, and the double-gate transistor are low temperature polysilicon transistors. It can be understood that each pixel circuit provided in the embodiment uses low-temperature polysilicon transistors. Since the cost of the low-temperature polysilicon transistors is low and manufacture process thereof is simple and mature, the embodiment can reduce product costs and improve product yield and quality.

The first transistor T1, the second transistor T2, the third transistor T3, the fourth transistor T4, the fifth transistor T5, and the double-gate transistor are all symmetrical transistors, that is, the source and the drain of each transistor can be interchanged without considering the relationship between the direction of the current and the source and drain of the transistor.

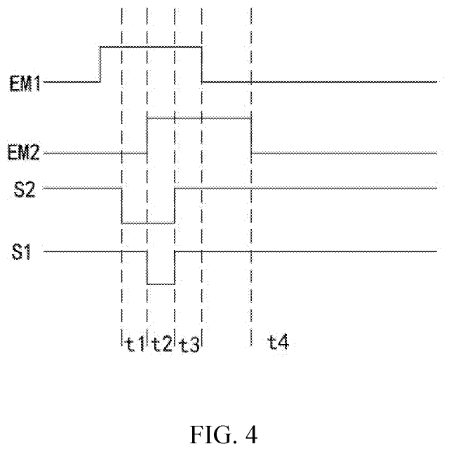

The operation principle of the pixel circuit provided in the embodiment will be described below by referring to FIG. 4. There are at least the following operation stages for the pixel circuit.

In the t1 time period, it relates to an initialization phase. In this phase, both of the second control signal input terminal EM2 and the second scan signal input terminal S2 input low-level signals. The fifth transistor T5, the third transistor T3, and the double-gate transistor are turned on. The reset signal input terminal V initializes the gate voltage of the first transistor T1.

In the t2 time period, it relates to a charge phase for the driving unit. In this phase, both of the first scan signal input terminal S1 and the second scan signal input terminal S2 input low-level signals, and both of the first control signal input terminal EM1 and the second control signal input terminal EM2 input high-level signals. The fourth transistor T4, the fifth transistor T5, and the double-gate transistor are turned on. The second transistor T2 and the third transistor T3 are turned off. The data signal input from the data signal input terminal Da charges the gate of the first transistor T1 and is stored in the second capacitor C2. At the same time, the reset signal input terminal V resets the input terminal of the light-emitting unit L.

In the t3 time period, it related to a coupling phase for the first capacitor C1. At the initial moment of this phase, the first scan signal input terminal S1 and the second scan signal input terminal S2 are switched to input high-level signals, the double-gate transistor is turned off, and the first control signal input terminal EM1 inputs a high-level signal. Under the coupling effect of the first capacitor C1, the internal potential of the double-gate transistor is coupled to a higher value. At the last moment of the t3 time period, the input signal of the first control signal input terminal EM1 changes to the low level from the high level. Under the coupling effect of the first capacitor C1, the internal potential of the double-gate transistor is coupled to a lower value and then less than the gate potential of the first transistor T1, thereby reducing or eliminating the leakage current from the double-gate transistor to the first transistor T1.

In the t4 time period, it related to a light-emitting phase. In this phase, both of the first control signal input terminal EM1 and the second control signal input terminal EM2 input low-level signals. The second transistor T2 and the third transistor T3 are turned on. Under the effect of the data signal stored in the second capacitor C2, the first transistor T1 drives the light-emitting unit L to emit light.

The present disclosure provides a pixel circuit. The pixel circuit comprises a driving unit, a light-emitting control unit, and a compensation unit. Both of the driving unit and the light-emitting control unit are electrically connected between a first power input terminal and a light-emitting unit. The light-emitting control unit is electrically connected to a control signal input terminal. The compensation unit is electrically connected between the driving unit and the light-emitting control unit, and a first capacitor is electrically connected between the compensation unit and the control signal input terminal. In the application, the first capacitor is electrically connected between the compensation unit and the control signal input terminal. The coupling effect of the first capacitor is used to reduce or eliminate the parasitic capacitance in the compensation unit, thereby decreasing the parasitic voltage in the compensation unit. This effectively alleviates the leakage problem of the compensation unit to the driving unit, enhances the stability of the pixel circuit, and improves the display quality of the display device.

An embodiment of the present disclosure also provides a display device. The display device comprises the pixel circuit described in any of the foregoing embodiments. The display device exhibits better display quality because it comprises the above-mentioned pixel circuit. Compared with the prior art, the leakage current of the internal circuit of the display device and the display problems caused by the leakage current are significantly improved.

It should be noted that although the application is disclosed as above in specific embodiments, the above-mentioned embodiments are not intended to limit the application. Those having ordinary skill in the art may make various modifications without departing from the spirit and scope of the application. Therefore, the protection scope of the application is subject to the scope defined by the claims.

1. A pixel circuit comprising:
a driving unit, electrically connected between a first power input terminal and a light-emitting unit;
a light-emitting control unit, electrically connected between the first power input terminal and the light-emitting unit and electrically connected to the driving unit, the light-emitting control unit being electrically connected to a control signal input terminal; and
a compensation unit, electrically connected between the driving unit and the light-emitting control unit, a first capacitor being electrically connected between the compensation unit and the control signal input terminal.

2. The pixel circuit of claim 1, wherein the compensation unit comprises a double-gate transistor, the double-gate transistor comprises a first channel and a second channel, a first terminal of the first capacitor is electrically connected between the first channel and the second channel.

3. The pixel circuit of claim 2, wherein the double-gate transistor comprises:
a first sub-transistor, comprising:
the first channel;
a first drain, electrically connected to the first terminal of the first capacitor; and
a first source, electrically connected between the driving unit and the light-emitting control unit; and
a second sub-transistor, comprising:
the second channel;
a second source, electrically connected to the first drain; and
a second drain electrically connected to the driving unit.

4. The pixel circuit of claim 3, wherein the first terminal of the first capacitor is electrically connected to the second source.

5. The pixel circuit of claim 4, wherein the light-emitting control unit comprises a first light-emitting control unit and a second light-emitting control unit, the control signal input terminal comprises a first control signal input terminal electrically connected to the first light-emitting control unit and a second control signal input terminal electrically connected to the second light-emitting control unit.

6. The pixel circuit of claim 5, wherein the first light-emitting control unit is electrically connected between the first power input terminal and the driving unit, the second light-emitting control unit is electrically connected between the driving unit and the light-emitting unit.

7. The pixel circuit of claim 6, wherein a second terminal of the first capacitor is electrically connected to the first control signal input terminal.

8. The pixel circuit of claim 6, wherein a second terminal of the first capacitor is electrically connected to the second control signal input terminal.

9. The pixel circuit of claim 6, further comprising:
a reset unit, electrically connected between a reset signal input terminal and the light-emitting unit;
an input unit, electrically connected between a data signal input terminal and the driving unit; and
a storage unit, electrically connected between the first power input terminal and the driving unit.

10. The pixel circuit of claim 9, wherein the driving unit comprises a first transistor, a gate of the first transistor is electrically connected to a drain of the double-gate transistor.

11. The pixel circuit of claim 10, wherein the first light-emitting control unit comprises a second transistor, the second light-emitting control unit comprises a third transistor, the gate, a source, and a drain of the first transistor are electrically connected to the drain of the double-gate transistor, a drain of the second transistor, and a source of the third transistor respectively, a gate, a source, and the drain of the second transistor are electrically connected to the first control signal input terminal, the first power input terminal, and the source of the first transistor respectively, a gate, the source, and a drain of the third transistor are electrically connected to the second control signal input terminal, the drain of the transistor, and the light-emitting unit respectively.

12. The pixel circuit of claim 11, wherein the input unit comprises a fourth transistor, a gate, a source, and a drain of the fourth transistor are electrically connected to a first scan signal input terminal, the data signal input terminal, and the source of the first transistor, respectively.

13. The pixel circuit of claim 12, wherein the reset unit comprises a fifth transistor, a gate, a source, and a drain of the fifth transistor are electrically connected to a second scan signal input terminal, the reset signal input terminal, and the drain of the third transistor, respectively.

14. The pixel circuit of claim 13, wherein the storage unit comprises a second capacitor, opposite two terminals of the second capacitor are electrically connected to the first power input terminal and the gate of the first transistor respectively.

15. The pixel circuit of claim 14, wherein a gate of the double-gate transistor is electrically connected to the second scan signal input terminal.

16. The pixel circuit of claim 15, wherein the double-gate transistor is a low-temperature polysilicon transistor.

17. The pixel circuit of claim 16, wherein the first, second, third, fourth, fifth transistors are low-temperature polysilicon transistors.

18. A display device comprising a pixel circuit, the pixel circuit comprising:
a driving unit, electrically connected between a first power input terminal and a light-emitting unit;
a light-emitting control unit, electrically connected between the first power input terminal and the light-emitting unit and electrically connected to the driving unit and a control signal input terminal; and
a compensation unit, electrically connected between the driving unit and the light-emitting control unit, a first capacitor being electrically connected between the compensation unit and the control signal input terminal.

19. The display device of claim 18, wherein the compensation unit comprises a double-gate transistor, the double-gate transistor comprises a first channel and a second channel, a first terminal of the first capacitor is electrically connected between the first channel and the second channel, and a second terminal of the first capacitor is electrically connected to the light-emitting control unit.

20. A pixel circuit comprising:
a driving unit, electrically connected between a first power input terminal and a light-emitting unit;
a light-emitting control unit, electrically connected between the first power input terminal and the light-emitting unit and electrically connected to the driving unit, the light-emitting control unit being electrically connected to a control signal input terminal;
a compensation unit, electrically connected between the driving unit and the light-emitting control unit, wherein the compensation unit comprises a double-gate transistor that comprises a first channel and a second channel; and
a first capacitor, electrically connected between the compensation unit and the control signal input terminal, wherein a first terminal of the first capacitor is electrically connected between the first channel and the second channel, and a second terminal of the first capacitor is electrically connected to the light-emitting control unit.
